(19) United States
(12) Patent Application Publication
(10) Pub. No.: US 2002/0123850 A1
(43) Pub. Date: Sep. 5, 2002

(54) System and method for providing information on secondary batteries for storing electric power

(75) Inventors: Tadahiko Miyoshi, Hitachi (JP); Manabu Madokoro, Hitachi (JP); Yasuji Kusakabe, Hitachi (JP); Hisamitu Hatou, Hitachi (JP)

Correspondence Address: Crowell & Moring LLP, The Evenson, Mckeown, Edwards & Lenehan, Intellectual Property Law Gr., 1200 G St., N.W., Suite 700, Washington, DC, 20005-3814, US

(73) Assignee: Hitachi, Ltd.

(21) Appl. No.: 09/941,726

(22) Filed: Aug. 30, 2001

(30) Foreign Application Priority Data
Mar. 1, 2001 (JP) 2001-057304

(51) Int. Cl. G01R 31/36

(52) U.S. Cl. 702/63

(57) ABSTRACT

The present invention relates to a system and method for providing information on secondary batteries for power storage to an electric power consumer in order to determine whether or not a secondary battery should be installed. A communication terminal (Internet terminal) sends to a consumer information including inquiries on electric power used by the consumer, and/or inquiries on limitations of an area and a height of a site usable for installation of a secondary battery at the location of the electric power consumer. A processor calculates, using the information on used electric power and/or the information on the limitations of the area and the height accepted from the electric power consumer, a capacity and a maximum output of a secondary battery suitable for the consumer, calculates the amount of saved power fee settled by the installation of the secondary battery, and/or calculates a cost cut effect for the electric power consumer resulting from purchase or lease of the secondary battery based on the price of the secondary battery, the amount of saved power fee and so on. The communication terminal sends the information on the capacity and the maximum output of the secondary battery, the amount of saved power fee, and/or the cost cut effect to the consumer.

### BACKGROUND OF THE INVENTION

The present invention relates generally to a system and a method for providing information on secondary batteries for storing electric power, and more particularly, to a system and a method for providing information on secondary batteries suitable for use in promoting sale and lease of secondary batteries to consumers in order to widely spread the utilization of secondary batteries which are effective for load leveling.

As described, for example, in JP-A-8-287958, 8-138731, 11-233137 and so on, a load leveling system using a secondary battery to store the electric power in the night and use the stored electric power in the daytime has significant effects on limiting the need for constructing power generating facilities as well as transmission and transformation facilities corrsponding to a daytime power consumption peak, and on improving the utilization ratio of such facilities, so that the load leveling system is expected to be widespread in the future.

While such secondary batteries may be installed in electric power substations in the suburbs of cities, larger installation areas are required for spreading the utilization of secondary batteries. In addition, since secondary batteries are preferably installed as near as possible to consumers for saving the transmission facilities, the secondary batteries should be installed at locations of consumers.

However, for an electric power consumer to possess a secondary battery for utilization in a building, an apartment house, or a solitary island, the consumer must install an appropriate secondary battery having a power and a capacity according to his power consumption pattern. With a conventional information providing method, however, the consumer experiences difficulties in selecting a secondary battery having a power and a capacity suitable for his power consumption pattern and the location at which the secondary battery is to be installed, and therefore difficulties in effectively utilizing the secondary battery for power storage.

Also, since consumers are not clearly informed of the effect possibly provided by installing secondary batteries, they would hesitate to determine whether they will install the secondary batteries. Of course, this problem would be solved if a seller of secondary batteries visited each electric power consumer to make detailed consultations. However, this would cause a labor cost which is added to the facility cost of the secondary battery, thereby decrasing the advantage of cost cut provided by the secondary battery for the consumers. This problem is critical particularly at an initial stage at which consumers plan to install secondary batteries. Since a relatively large number of consumers are interested in the installation of secondary batteries at the initial stage, a large labor cost will be required for visiting each of interested consumers to make consultations. For these reasons, it is an essential consideration for widely spreading the secondary batteries to assist electric power consumers to determine, particularly at the initial stage, the installation of the secondary batteries, and to reduce the cost for the sales activities.

When a sodium/sulfur battery is used for a secondary battery for power storage, it is desirable to clarify the effect of installing the secondary battery in consideration of maintenance and management costs for hazardous material handling, and a power cost required for a heater for keeping the battery temperature. However, insufficient investigations have been so far made on this subject.

### SUMMARY OF THE INVENTION

It is an object of the present invention to provide a system and a method for providing information on secondary batteries for power storage, which is useful for an electric power consumer to determine whether or not a secondary battery should be installed.

To achieve the above object, the present invention provides a system for providing information on secondary batteries for storing electric power. The system includes communication means for sending to an electric power consumer information including inquiries on electric power used by the consumer, and/or inquiries on limitations of an area and a height of a site usable for installation of a secondary battery at the location of the consumer, and a processor for calculating, using the information on used electric power and/or the information on the limitations of the area and the height accepted from the consumer, a capacity and a maximum output of a secondary battery suitable for the consumer, calculating the amount of saved power fee settled by the installation of the secondary battery, and/or calculating a cost cut effect for the consumer resulting from purchase or lease of the secondary battery based on the price of the secondary battery, the amount of saved power fee and so on, wherein communication means send the infromation on the capacity and the maximum output of the secondary battery, the amount of saved power fee, and/or the cost cut effect to the consumer.

The system of the invention as described can supply information on secondary batteries useful for a consumer to determine whether a secondary battery should be installed.

Also, to achieve the above object, the present invention provides a method of providing information on secondary batteries for storing electric power. The method includes the steps of sending to an electric power consumer information including inquiries on electric power used by the consumer, and/or inquiries on limitations of an area and a height of a site usable for installation of a secondary battery at the location of the consumer, calculating, using the information on used electric power and/or the information on the limitations on the area and the height acquired from the consumer, a capacity and a maximum output of a secondary battery for power storage suitable for the consumer, calculating the amount of saved power fee settled by the installation of the secondary battery, and/or calculating a cost cut effect for the consumer resulting from purchase or lease of the secondary battery based on the price of the secondary battery, the amount of saved power fee and so on, and sending the information on the capacity and the maximum output of the secondary battery, the amount of saved power fee, and/or the cost cut effect to the consumer.

The method of the invention as described above can supply information on secondary batteries useful for a consumer to determine whether a secondary battery should be installed.

### BRIEF DESCRIPTION OF THE DRAWINGS

FIG. 1 is a block diagram illustrating the configuration of the system for providing information on secondary batteries according to one embodiment of the present invention.

FIG. 2 is a flow chart illustrating details of a method of providing information on secondary batteries according to one embodiment of the present invention;

FIG. 3 is a graph showing the relationship between the amount of discharged power and a maximum output of a secondary battery for use in the method of providing information on secondary batteries according to the embodiment of the present invention; and

FIG. 4 is a graph showing the charge/discharge characteristics of a sodium/sulfur battery for use in the method of providing information on secondary batteries according to the embodiment of the present invention.

### DETAILED DESCRIPTION OF THE EMBODIMENT

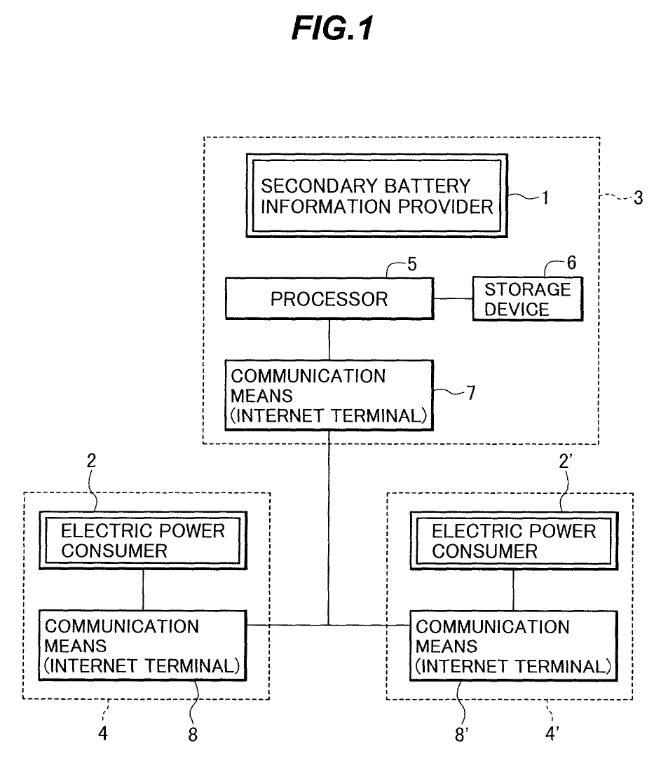

In the following, a system and a method for providing information on secondary batteries for power storage (hereinafter simply called the “secondary batteries”) according to one embodiment of the present invention will be explained with reference to FIGS. 1 through 4.

To begin with, the configuration of the system for providing information on secondary batteries according to this embodiment will be described with reference to FIG. 1.

FIG. 1 is a block diagram illustrating the configuration of the system for providing information on secondary batteries according to the embodiment of the present invention.

In the configuration for providing information on secondary batteries such as a sodium/sulfur battery, a lithium ion battery, a lead storage battery, and a redox-flow battery, an information provider 1 and an electric power consumer (hereinafter simply called the “consumer”) 2 are involved, and included in an information providing system 3 and an information receiving system 4, respectively. Here, the information provider 1 may be a seller, a lender, a manufacturer, or an advertiser of secondary batteries.

The information providing system 3 installed at the information provider 1 for providing information on secondary batteries comprises a processor 5, a storage device 6, and a communication means 7. The processor 5 calculates a capacity and a maximum output of a secondary battery for a consumer, as well as the amount of saved power fee, a cost cut effect, and so on possibly provided by the secondary battery. The storage device 6 stores information required for calculations, and results of calculations. The communication means 7 may be an electronic mail, an Internet terminal, or the like. The communication means 7 promotes secondary battery sales and lease activities through communications of information with the electric power consumer 2. A home page may also be used as the communication means 7, in which case the information provider 1 can readily communicate information with a plurality of consumers 2, 2′. The storage device 6 and the communication means 7 may be incorporated in the processor 5.

While a lithium ion battery, a lead storage battery, a redox-flow battery and so on may be used for the secondary battery, a sodium/sulfur battery is particularly suitable for the secondary battery. The sodium/sulfur battery is advantageous in its compact size, high energy density, high battery charging/discharging efficiency, and good compatibility with mass production because of using abundant materials. In addition, since the sodium/sulfur battery only requires a small space for installation, it can be installed in a building, an apartment house, and so on, and is particularly suitable for use by consumers to maximize its effectiveness in the load leveling problem.

On the other hand, information receiving systems 4, 4′ installed at the consumers 2, 2′ also comprise communication means 8, 8′, respectively, such as an electronic mail and an Internet terminal. The consumers 2, 2′ may communicate information with the information provider 1 through the communication means 8, 8′. The communication means 7, 8, 8′ may also be a postal mail service, a facsimile, a telephone and so on.

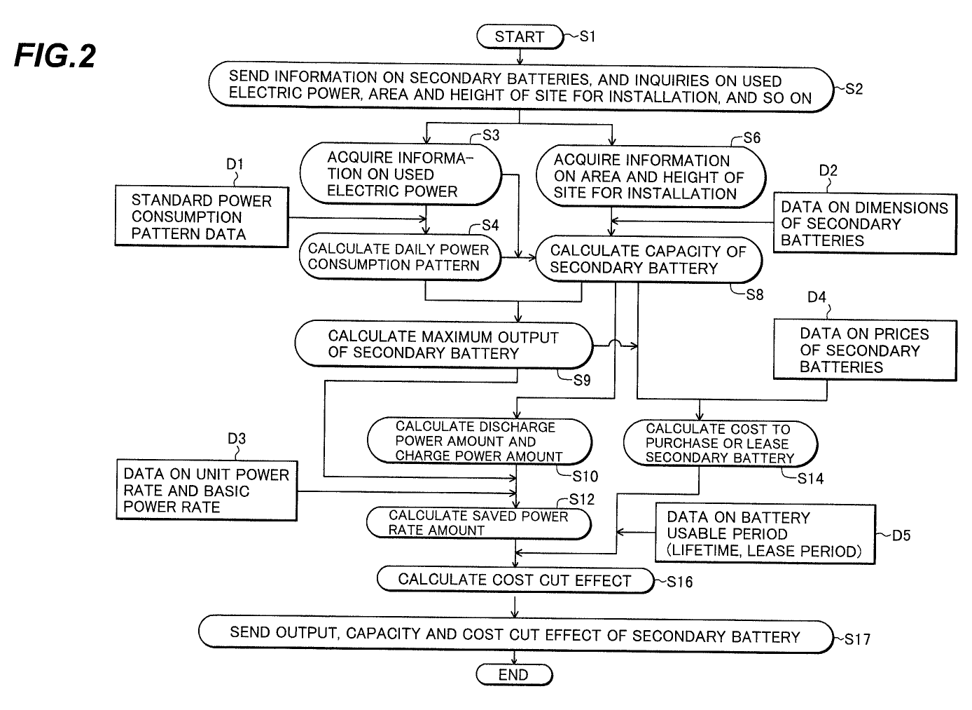

Next, a method of providing information on secondary batteries according to this embodiment will be described with reference to FIG. 2.

FIG. 2 is a flow chart illustrating details of the method of providing information on secondary batteries according to one embodiment of the present invention. First at step S1, the communication means 7 of the information providing system 3 is operated to start the processing involved in the information providing method. Then, at step S2, the information providing system 3 sends information on secondary batteries to the consumer 2, as well as inquiry items about the electric power used by the consumer and inquiry items about limitations of the area and the height of a site at which a secondary battery is to be installed at the consumer's location.

Here, the information may be sent directly from the information provider 1 to the consumer 2 using the communication means 7 such as the Internet, or using a home page as the communication means 7 such that the consumer 2 may access the home page through the communication means 8 of an Internet terminal to read the information. For calculating the capacity and the maximum output of a secondary battery suitable for each consumer using the information accepted from the consumer 2 based on the inquiry items, it is desirable to use a format which enumerates items required for the calculation as inquiry information. The communication means 7 may also be a postal mail service, a facsimile, a telephone and so on. Further, the information on secondary batteries may be, for example, the structure, size, capacity and output of a standard secondary battery, and a cost cut effect provided by the installation of the secondary battery.

Next, at step S3, the information providing system 3 accepts information on used electric power returned from the consumer. Further, at step S4, the information providing system 3 calculates a daily power consumption pattern based on the information on used electric power accepted at step S3.

If the information returned from the consumer indicates an actual or estimated power consumption pattern in the past or at present, or a scheduled power consumption pattern in the future, these power consumption patterns may be used as they are. On the other hand, when the information returned from the consumer relates to the types, amounts, power consumption, operating hours and so on of electric machines which dominantly determine the amount of consumed power, a power consumption pattern may be estimated based on this information.

On the other hand, when the information providing system 3 accepts information on the amount of consumed power and purpose of an electric machine, or information on the area, purpose, consumed power and so on of a building, as the information sent from the consumer, the processor 5 may calculate and estimate a daily power consumption pattern using standard data D1 of a power consumption pattern corresponding to these purposes and so on, as well as the information from the consumer. The standard data D1 on the power consumption pattern is previously stored in the storage device 6.

At step S6, the information providing system 3 accepts information on limitations of the area and height of a site at which a secondary battery is to be installed.

Then, at step S8, the information providing system 3 calculates an allowable capacity of a secondary battery suitable for the site. The allowable capacity of a secondary battery can be calculated using the information on the area and the height of the site accepted at step S6, and data D2 on the dimensions of secondary batteries previously stored in the storage device 6. The allowable capacity of battery is desirably calculated by the processor 5 using the data previously stored in the storage device 6. Also, the secondary battery requires an AC/DC converter and an associated controller which should be installed together with the secondary battery. It is therefore necessary to consider data of dimensions of these devices corresponding to the capacity and the power of a particular secondary battery, when the allowable capacity is calculated for the secondary battery. Although it should be noted that the area and the height required for the AC/DC converter and the controller depend on the maximum output of the associated battery, the area and the height of the secondary battery are generally larger than those of the AC/DC converter and the controller, so that the area and the height required of the AC/DC converter and the controller can be assumed as substantially constant. Also, if the limited area and height for an installation site are sufficiently large, the allowable capacity of a secondary battery will be excessively large in view of the amount of used power. In this case, the capacity is preferably calculated from the amount of actually used power. On the other hand, if the allowable capacity is small due to the limitations of the site, the capacity of an actually installed secondary battery is limited to the capacity calculated from the limitations of the site.

Alternatively, the capacity of a secondary battery suitable for installation can be calculated from the information on used power returned from the consumer 2, or the amount of used power determined from the power consumption pattern calculated at step S4. The capacity of battery can be determined by dividing the amount of used power by an average discharge voltage and the efficiency of the AC/DC converter. If a load consumes a DC power, the amount of used power may be divided by an average discharge voltage.

The capacity of the secondary battery may be sometimes calculated based on both information of steps S3, S6.

Since the merit of installing a secondary battery lies in a power cost cut for a consumer, it is desirable to select the capacity which maximizes the cost cut effect for the consumer 2 when the secondary battery is installed, as described later. For this purpose, it is desirable to calculate the cost cut effect for each of several capacities to select the optimal capacity based on the result of calculation, or to make discussion for the capacity arrangement of a battery to be installed with the consumer 2 based on these data.

Next, at step S9, the information providing system 3 calculates a maximum output of the secondary battery using the daily power consumption pattern and the capacity of the secondary battery, calculated at steps S4, S8, respectively.

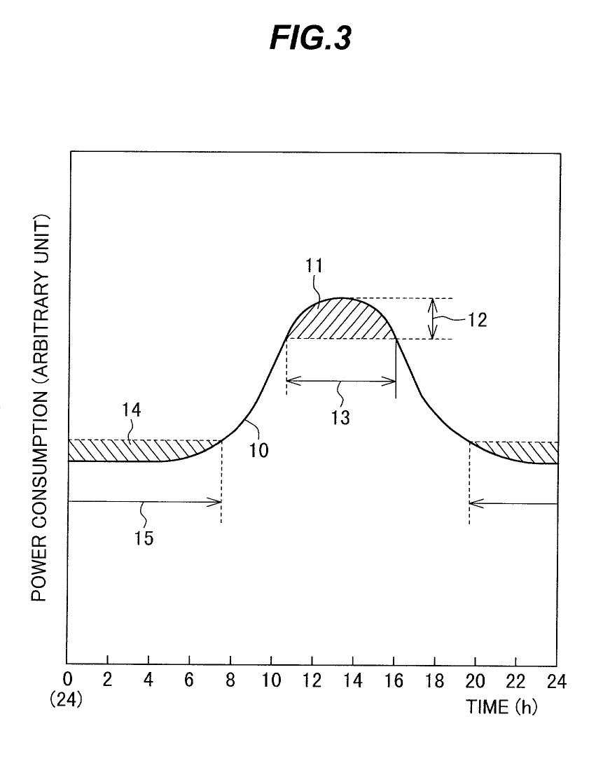

Now, referring to FIG. 3, the relationship between the amount of discharge power and a maximum output will be illustrated for a secondary battery for use in the method of providing information on secondary batteries according to this embodiment.

FIG. 3 is a graph showing the relationship between the amount of discharge power and a maximum output of a secondary battery for use in the method of providing information on secondary batteries according to the embodiment of the present invention. It should be noted that this example shows the relationship between the amount of discharge power and a maximum output of a secondary battery including an AC/DC converter.

A daily power consumption pattern 10 in FIG. 3 includes the amount of discharge power 11 of the secondary battery; a maximum output 12 of the secondary battery; and a discharge time period 13. In other words, a power pattern remained after the amount of discharged power 11 is subtracted from the power consumption pattern 10 to is a pattern of power supplied from a power system or a power generator to a consumer.

The amount of discharge power of the battery is calculated by multiplying the battery capacity by an average discharge voltage and the efficiency of an AC/DC converter, or by multiplying the battery capacity by an average discharge voltage when a DC load is used. The maximum output 12 can be calculated using the calculated value of the amount of discharge power and the power consumption pattern 10 in FIG. 3. Also, when the battery capacity is determined from the amount of used power in the calculation of the battery capacity at step S8, the maximum output can be calculated using this amount of used power as the amount of discharge power of the secondary battery.

For calculating the maximum output using the characteristic of the power consumption pattern shown in FIG. 3, the processor 5 is used, and the value of consumed power per hour in a day is stored in the storage device 6. Then, the maximum output can be calculated by establishing the relationship between the amount of discharge power and the maximum output using the stored data. Alternatively, the daily power consumption pattern may be approximated to a mathematical function which is then used to calculate the maximum output from the amount of discharge power. In this way, the maximum output can be determined for the secondary battery using the amount of discharge power determined from the capacity of the secondary battery suitable for installation, and the daily power consumption pattern.

In some applications, it is possible to operate a secondary battery at constant power or in such a manner that the power consumption pattern curve shows a trapezoidal characteristic. In these cases, the maximum output can be calculated for the secondary battery from the capacity of the secondary battery or the amount of discharge power and the operating hours and/or the shape of an operating pattern. However, the basic power rate can be maximally reduced to realize the large power fee saving, as described later, by determining the maximum output of the secondary battery based on the power consumption pattern as discussed above. It is therefore particularly desirable for increasing the cost cut effect by the installation of the secondary battery to calculate the maximum output using the power consumption pattern in FIG. 3, and to discharge the secondary battery based on this. While all power consumed by a consumer may be supplied by the capacity of the secondary battery, a larger capacity results in a larger cost for purchase or lease of the secondary battery. Therefore, desirably, a part of the consumed power is supplied by the secondary battery as can be seen in FIG. 3 for increasing the cost cut effect. In this case, with the application of the secondary battery as shown, the power fee reduction can be maximized by discharging the secondary battery to minimize the peak of power supplied from the power system or the power generator.

Though not shown, when the maximum output is determined from power using conditions, contrary to the foregoing, the processor 5 can calculate the amount of discharge power from the maximum output using the relationship of FIG. 3, and divide the amount of discharge power by an average discharge voltage and the efficiency of the AC/DC converter, or by the average discharge voltage for a DC load, to obtain the battery capacity. Further, when a part of the capacity of the secondary battery is used for an emergency power supply, the amount of discharge power of the secondary battery may be selected to be equal to the sum of the amount of discharge power used by electric devices such as that indicated by 11 in FIG. 3 and the amount of discharge power required for the emergency power supply, and the battery capacity may be determined from this amount of discharge power. When the secondary battery and the AC/DC converter are actually installed at the location of the consumer 2, it is desirable to slightly increase the capacity of the secondary battery and the maximum output of the AC/DC converter from the foregoing calculated values to ensure a margin for the battery facilities in consideration of seasonal variations and day-by-day variations of the daily power consumption pattern.

The relationship between the amount of discharge power of the secondary battery and the battery capacity for determining the size of the secondary battery is calculated, in a strict manner, using a constant current or constant power charge/discharge characteristics of the secondary battery.

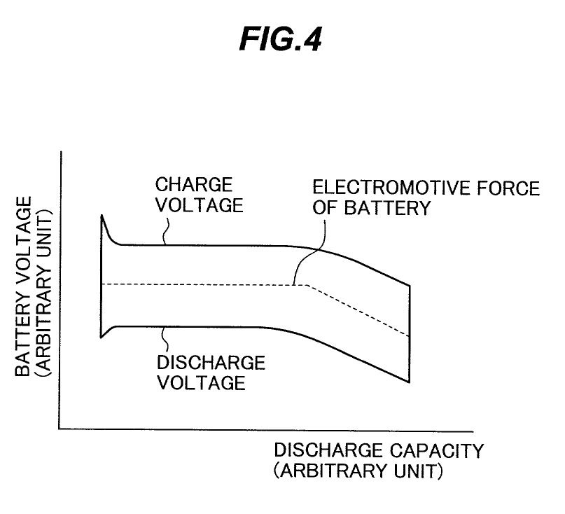

Now, referring to FIG. 4, the charge/discharge characteristics will be described for a sodium/sulfur battery for use in the method of providing information on secondary batteries according to this embodiment.

FIG. 4 is a graph showing the charge/discharge characteristics of a sodium/sulfur battery for use in the method of providing information on secondary batteries according to this embodiment.

The discharge power W(t), which is the output at each time t is given by the following equation (1):

W(t)=η×[E−I(t)×R]×I(t) (1)

where is a conversion efficiency of an AC/DC converter for converting from DC to AC; E is an electromotive force of a battery; I is a current of the battery; R is the resistance of the battery; and (E−I(t)×R) corresponds to a discharge voltage. For a DC load, η in the equation (1) is set to one.

The amount of discharge power is given by the integral of the discharge power over time (∫W(t)dt), and the battery capacity is given by the integral of the current of the battery over time (∫I(t)dt). The discharge power is integrated over a discharge time period 13 as an example shown in FIG. 3.

When a sodium/sulfur battery is used for the secondary battery, the battery electromotive force E decreases as the discharge capacity on the horizontal axis is larger than a predetermined value, as can be seen in FIG. 4. For this reason, for calculating the relationship between the battery capacity and the amount of discharge power for discharging in accordance with the power consumption pattern 10, the amount of discharge power is first assumed, the discharge power at each discharge time is calculated from the power consumption pattern of FIG. 3, the current of the battery is calculated at each discharge time from the electromotive force derived from FIG. 4 and the resistance of the battery during the discharging, and this current of the battery is integrated over the discharge time period 13.

The amount of discharge power can be correctly calculated from the relationship between the battery capacity and the amount of discharge power, thus established, and the previously determined battery capacity. For a strict calculation, the processor 5 is desirably used to paractice the foregoing method. Conversely, for correctly calculating the battery capacity from the amount of discharge power, a similar calculation to the foregoing may be performed using the equation (1).

When the battery is used under a condition that the electromotive force in FIG. 4 is constant, the calculation can be readily performed. In addition, since the average discharge voltage is higher, the same amount of discharge power can be supplied with a smaller battery capacity. As a result, the amount of charge power is reduced so as to save more power fee.

On the other hand, if the battery is utilized up to a region in which the electromotive force in FIG. 4 decreases according to the incrase of the discharge capacity, the battery can be used in a wider range, resulting in a reduction of the number of batteries for providing a certain amount of discharge power. In the latter case, the range of the discharge capacity in FIG. 4 is selected from a usable range of the battery which has been determined in consideration of the battery capacity and battery life, and the aforementioned equation (1) is used for calculation sonsidering the variations in the electromotive force and the resistance of the battery calculated therefrom. In this case, the electromotive force and the discharge voltage, or the resistance of the battery for each discharge capacity indicated in FIG. 4 may be stored in the storage device 6 for use in the calculation, or the electromotive force and the discharge voltage in FIG. 4 may be approximated to a mathematical function for use in the calculation. Alternatively, instead of the foregoing calculation, averagedischarge power can be derived using an operation pattern such as that shown in FIG. 3; a constant power operation, or trapezoidal operation, an average discharge voltage be calculated from the averagedischarge power and the relationship shown in FIG. 4; and the relationship between the amount of discharge power and the battery capacity can be established using the averaged discharge voltage instead of (E−I(t)×R) in the equation

The latter method is advantageous because the calculation is simplified, and the amount of discharge power can be readily calculated from the battery capacity found at step S8. Then, the maximum output is derived from the thus calculated amount of discharge power and an operation pattern such as that shown in FIG. 3, as described above.

Turning back to FIG. 2, the information providing system 3 next calculates at step S10 the amount of discharge power and the amount of charged power using the capacity of the secondary battery calculated at step S8. If the amount of used power (amount of discharge power) has been determined for calculating the battery capacity at step S8, or if the amount of discharge power has been calculated for calculating the maximum output at step S9, these values can be used. When the amount of discharge power is newly calculated from the battery capacity, the equation (1) may be used as described above.

On the other hand, for calculating the amount of charge power from the battery capacity, the following equation (2) is used:

W′(t)=1/η′×[E+1(t)×R′]×I(t) (2)

where W′ is the charge power at each time t; η′ is a conversion efficiency of the AC/DC converter for converting from AC to DC; and R′ is the resistance of the battery during charging. The amount of charge power is given by the integral of the charge power over time (∫W′(t)dt), and the battery capacity is given by the integral of the current of the battery over time (∫I(t)dt).

Generally, the battery is charged with a constant current, in which case, a charging time period is calculated from the battery capacity derived at step S8 and the charging current. Then, a charge voltage (E+I(t)×R′) is calculated from the electromotive force derived from FIG. 4 and the resistance of the battery, and the amount of charge power is calculated from the equation (2).

When the battery is used up to a range in which the electromotive force changes, a change in the electromotive force, the resistance of the battery or the charge voltage may be taken in the calculation. Advantageously, this method enables the processor 5 to correctly calculate the amount of charge power.

Alternatively, the amount of charge power may be simply calculated from the battery capacity by calculating an average charge voltage using the data in FIG. 4, and using the average charge voltage instead of E+I(t)×R′ in the equation (2). Further, as can be seen in FIG. 3, when the battery is charge such that the power consumption including the charge power during the charging is constant, the amount of charge power 14 is integrated over a charging time period 15. Therefore, the relationship between the battery capacity and the amount of charge power may be established in a manner similar to the foregoing method by first assuming the amount of charge power, calculating charge power at each charging time from the power consumption pattern shown in FIG. 3, calculating a current of the battery at each charging time from the electromotive force found from FIG. 4, the resistance of the battery during the charging, and the equation (2), and integrating the current of the battery over the charging time period 15 to derive the battery capacity. The amount of charge power can be calculated from the relationship between the thus derived battery capacity and the amount of charge power, and the given battery capacity.

The calculation of the amount of charge power may be simplified by calculating the battery efficiency resulting from charging/discharging using the battery characteristics shown in FIG. 4, multiplying the battery efficiency by the efficiency (η×η′) of the AC/DC converter to find the battery system efficiency, dividing the amounts of discharge power calculated at steps S8, S9, S10 by the battery system afficiency to derive the amount of charge power. When the battery is used in a range in which the electromotive force of the battery is constant, a predetermined amount of discharge power is supplied with a smaller battery capacity, as described above. Consequently, the amount of charge power is reduced to save more power fee, as described later. It should be noted that the sodium/sulfur battery tends to shorten the battery life when the battery is used up to a range in which the electromotive force decreases, so that the battery is preferably used in a range in which the electromotive force is constant, from this point of view as well.

Next, at step S12, the information providing system 3 calculates the amount of saved power rate (fee) using the amount of discharge power, the amount of charge power, and the maximum output calculated in the manner described above, as well as data D3 such as a unit power rate (fee) and a basic power rate (fee). The data D3 including the unit power rate and the basic power rate are desirably stored in the storage device 6 for use by the processor 5 to calculate the amount of saved power rate.

The power fee is generally defined as the sum of a basic power rate determined by the maximum used power supplied from a power system or a power generator and a used power rate determined by the product of the used power and a unit power rate a unit price of used power, and the unit power rate is lower in the nighttime than during daytime. The basic power rate, is detemined by required eak power, and decreases usually with the decrase of the maximum used power. Therefore, the power fee is saved by the installation of the secondary battery which provides a reduction in the bassic power rate resulting from lower maximum daytime power consumption (corresponding to the aforementioned maximum output which is determined by the output power of the AC/DC converter by discharging the battery, and is maximized when the secondary battery isdischarge in accordance with a power consumption pattern), and daytime utilization of power charge in the nighttime. In other words, the amount A of saved power rate (fee) is given by the following equation (3):

Δ=Difference in Basic Power Rate+Daytime Unit Power Rate×Amount of Discharge Power−Night Unit Power Rate×Amount of Charge Power (3)

Generally, the amount of saved power rate is calculated in months or in years, and for this purpose, it is necessary to consider the number of operating days of the consumer as well as the amount of discharge power and the amount of charge power per day. Also, in some cases, seasonal variations in the amount of consumed power, i.e., the amount of discharge power should be taken into consideration.

The sodium/sulfur battery is provided with a heater for holding the battery at temperature of 300-C. or higher, so that the amount of saved power rate (fee) must be calculated by subtracting the power fee caused by the heater from the result of the equation (3). The amount of power consumed by the heater varies according to a particular battery operating pattern, and is larger as the number of inoperative days is larger and the ambient temperature is lower. It is therefore desirable, particularly for improving the accuracy of calculating the amount of saved power rate, to include information on the number of inoperative days of the consumer and/or information on the temperature at the site where the secondary battery is installed in the inquiries at step S2, to calculate the amount of power consumed by the heater, using such information, and to calculate the amount of saved power rate at step S12 including the power fee for the heater.

At step S14, the information providing system 3 calculates the facility cost for the secondary battery using the battery capacity calculated at step S8; the maximum output calculated at step S9; and the data D4 on the price of the battery, to calculate a cost for the consumer 2 to purchase or lease the secondary battery.

The price of the battery is mainly determined by the battery capacity, while the price of the AC/DC converter is mainly determined by a maximum output, so that information on both the battery capacity and the maximum output is required to calculate the facility cost for the secondary battery including the AC/DC converter and an associated controller. In addition, for a battery lease cost, a lease period, later described, must be taken into consideration. Also, a cost required for transportation and installation of the battery must be included in the purchase cost or lease cost.

Next, at step S16, the information providing system 3 calculates the cost cut effect resulting from the installation of the secondary battery using the amount of saved power rate (fee) calculated at step S12, the purchase or lease cost for the battery calculated at step S14, and data D5 on usable period of the battery calculated from the lifetime and guaranteed period of the battery or a lease period contracted with the consumer.

When the consumer 2 purchases the battery, the amount of saved power rate (fee) per year is calculated by (Amount of Annually Saved Power Rate−Initial Investment×Interest Rate). The aggregate amount of the cut cost resulting from the utilization of the secondary battery for certain years exceeds the initial investment, and the amount of subsequent cut cost represents the cost cut effect. On the other hand, when the consumer 2 leases the battery, the amount of saved power rate (fee) per year is calculated by (Amount of Saved Power Rate per Year−Cost for Battery Lease). Generally, since the battery lease cost varies depending on a lease period, the information providing system 3 may be provided with a desired lease period from the consumer to calculate the battery lease cost based on the desired period, or may use the lease period as a parameter to calculate the cost cut effect using a battery lease cost for each lease period. If a maintenance/repair cost is required for the secondary battery, this cost must be subtracted from the amount of cut cost to eventually derive the cost cut effect. When the consumer 2 deputes the maintenance and management of the secondary battery to the information provider 1, a maintenance/management cost is subtracted from the amount of cut cost to derive the cost cut effect.

The secondary battery can be automatically operated, and remotely monitored by the information provider 1, i.e., a seller, a manufacturer, or the like for maintenance and management. As a result, the consumer 2 can exclude the effort of operation, maintenance and the management of the battery, and experts are assigned to the maintenance and management, thereby improving the reliability of the secondary battery and spreading the utilization of the secondary battery. Particularly, when a sodium/sulfur battery is used as a secondary battery, the operation, maintenance and management of the battery must be deputed to a worker qualified as a hazardous material operator because of the regulation of the Fire Fighting Law. Therefore, if a consumer himself is to operate, maintain and manage the secondary battery, the sodium/sulfur battery cannot be an option. On the other hand, when a seller or a manufacturer operates, maintains and manages the secondary battery, a qualified worker or engineer can be readily selected. In addition, one and the same qualified worker or engineer may maintain and manage a plurality of secondary batteries to reduce personnel working for the operation, maintenance and management, resulting in a reduction in the maintenance and management cost.

Though not shown, if a battery which contains hazardous materials such as a sodium/sulfur battery is used as the secondary battery, the consumer is desirably inquired at step S2 whether he wishes to depute the maintenance and the management of the battery. If the consumer so wishes, the cost cut effect is calculated at step S16 including the cost required for the maintenance and the management such as remote monitoring. By doing so, the battery can be readily maintained and managed by a qualified worker, correctly operated in conformity to the law, thereby improving the reliability and the safety of the battery. In addition, the consumer need not be responsible for the maintenance and the management of the secondary battery, so that the secondary battery can be readily utilized. Even with a battery which contains no hazardous materials, it is desired to remotely monitor the operation of the battery for facilitating the consumer's utilization of the battery, in which case, desirably, the consumer is inquired whether or not he wishes to depute the maintenance and the management of the battery, and the cost cut effect is calculated including the maintenance/management cost associated with remote monitoring and so on.

Finally, at step S17, the information providing system 3 sends the information on the capacity and the maximum output of the secondary battery calculated in the manner described above, and/or the information on the cost cut effect to the consumer 2 through the communication means 7. In this way, the consumer 2 can determine whether or not he will install the secondary battery.

For facilitating the consumer's determination, the information on the cost cut effect is desirably sent to the consumer together with the information on the capacity and the maximum output of the secondary battery. In addition, the information on the amount of saved power fee, and the information on the purchase or lease cost for the secondary battery may be sent instead of the cost cut effect. Particularly, it is desirable that the information on the amount of saved power fee and a purchase cost or a lease cost are sent to the consumer together with the cost cut effect. Furthermore, the information provider 1 may discuss with the consumer through the communication means 7, 8 at a later time. Alternatively, a sales person may visit the consumer as required to enter into negotiations with the consumer for sale or lease of the secondary battery.

As described above, this embodiment provides a system and a method for providing information on secondary batteries for promoting sale and lease of secondary batteries, wherein the information provider 1 provides information on secondary batteries through the communication means 7, 8, and calculates the capacity and the maximum output of a secondary battery suitable for the consumer 2, the amount of saved power fee, and the cost cut effect using the processor 5 and the storage device 6 as required, based on information accepted from the consumer 2, and sends these data to the consumer.

Advantageously, the information providing system and method according to this embodiment can select a secondary battery having an output and a capacity suitable for a particular power consumption pattern of the consumer and a site at which the secondary battery is to be installed, through communications of information using the communication means, and clarifies the effect provided by installing the secondary battery to the consumer, thereby permitting the consumer to exactly determine whether a secondary battery should be installed.

Through communications of information, sellers or manufactures may visit consumers less frequently for sale and lease of secondary batteries, so that a labor cost associated therewith can be reduced. The consumers in turn can benefit from a reduction in the sales price of the secondary battery or a lease cost.

As a result, the secondary batteries can become popular with effective utilization of night power, so that the power supplier can benefit from a higher utilization ratio of the power generation facilities and the transmission/transformation facilities by virtue of the load leveling.

Further, by remotely monitoring the maintenance and the management of the secondary battery, the consumer can leave off exclude the efforts of operation, maintenance and management, and experts are assigned to the maintenance and the management, thereby improving the reliability of the secondary battery and spreading the utilization of the secondary battery. When the consumer leases a secondary battery, the consumer advantageously eliminates an initial investment for purchasing the secondary battery and readily starts using the secondary battery.

As a specific example, as illustrated in FIG. 1, the information provider 1, which may be a seller of secondary batteries, may use the processor 5; the storage device 6; and the communication means 7 including an Internet terminal, and create a home page for secondary batteries using the communication means 7 to send to consumers information on secondary batteries, inquiries on the electric power used by consumers, inquiries on limitations on the area and the height of a site for installing a secondary battery at the consumer's location, an inquiry as to whether or not the consumer wishes to depute the maintenance and the management of a secondary battery, when it is a sodium/sulfur battery, and inquiries on the temperature at the site at which the secondary battery is installed and/or the number of inoperative days, and so on. On the other hand, consumers 2, 2′ may access the home page using their own communication means 8, 8′ including Internet terminals to read the information on the home page. As a result, if a consumer is interested in the installation of a secondary battery, the consumer may send replies to the inquiries to the information provider 1 through the communication means 8, 8′. Next, based on the replies, the information provider 1 determines characteristics of a secondary battery suitable for each consumer using the processor 5, for example, the capacity and the maximum output of a sodium/sulfur battery, calculates the amount of saved power fee resulting from the installation of the secondary battery, a battery purchase or lease cost, a maintenance/management cost for the sodium/sulfur battery and power consumed by an associated heater, and so on. Then, the information provider 1 calculates the cost cut effect for the consumer possibly resulting from the installation of the secondary battery based on the result of calculations, and sends the information to the consumer through the communication means 7. Upon receipt of the information, the consumer may determine based on the cost cut effect whether or not the secondary battery should be installed, or select a purchase or lease of the secondary battery, and communicate the result to the information provider 1 through the communication means 8, 8′. In this way, the consumer can conclude a contract for a purchase or lease of a secondary battery through information exchange by the communication means, so that a seller or a manufacture may visit the consumer less frequently so as to reduce a labor cost, resulting in a reduction in the sales price and lease cost of the secondary battery.

In the foregoing manner, the consumer benefits from a reduction in the sale price or lease cost of the secondary battery resulting from a reduction in the labor cost required for promoting sale and lease of secondary batteries. In addition, the utilization of secondary batteries can become poular, and the utilization ratio of the power generation facilities and the transmission/transformation facilities is increased by the load leveling. Furthermore, it is possible to promote correct maintenance and management of batteries which contain hazardous materials and spread the utilization of sodium/sulfur batteries and so on.

According to the present invention, information on secondary batteries can be provided for use by a consumer to determine whether or not a secondary battery should be installed.

What is claimed is:

1. A system for providing information on secondary batteries for storing electric power, comprising:
communication means for sending to an electric power consumer information including inquiries on electric power used by the consumer, and/or inquiries on limitations of an area and a height of a site usable for installation of a secondary battery at the location of the consumer; and
a processor for calculating, using the information on used electric power and/or the information on the limitations of the area and the height accepted from the consumer, a capacity and a maximum output of a secondary battery for power storage suitable for the consumer, calculating the amount of saved power fee settled by the installation of the secondary battery, and/or calculating a cost cut effect for the consumer resulting from purchase or lease of the secondary battery based on the price of the secondary battery, the amount of saved power fee and so on,
and communication means sending the informaiton on the capacity and the maximum output of the secondary battery, the amount of saved power fee, and/or the cost cut effect to the consumer.

2. An information providing system according to claim 1, wherein:
said communication means comprises an electronic mail or the Internet.

3. An information providing system according to claim 1, wherein:
said processor calculates a capacity of a secondary battery suitable for installation from the information on used electric power and/or the information on the limitations of the area and the height of the site for installation, and/or calculates a maximum output of the secondary battery using the capacity and a daily power consumption pattern of the used electric power.

4. An information providing system according to claim 1, wherein:
said processor calculates a maximum output of the secondary battery suitable for installation from the information on used electric power, and/or calculates a capacity of the secondary battery using the maximum output and a daily power consumption pattern of the used electric power.

5. An information providing system according to claim 1, wherein:
said processor calculates the amount of saved power fee using the maximum output of the secondary battery, the amount of discharge power and the amount of charge power of the secondary battery, and data on a unit power rate and a basic power rate, and/or calculates the cost cut effect using the price of the secondary battery, a use period or a lease period, and the amount of saved power fee.

6. An information providing system according to claim 1, wherein:
the inquiries sent to the consumer include an inquiry as to whether or not the consumer wishes to depute maintenance or management of the secondary battery, and when the consumer so wishes, said processor calculates the cost cut effect including a cost required for the maintenance or the management.

7. An information providing system according to claim 1, wherein:
said processor calculates the amount of saved power fee including the amount of power consumed by a heater associated with a sodium/sulfur battery, said amount of power being calculated using the information of the number of inoperative days of the consumer and/or a temperature at the site for installation.

8. A method of providing information on secondary batteries for storing electric power, comprising the steps of:
sending to an electric power consumer information including inquiries on electric power used by the consumer, and/or inquiries on limitations of an area and a height of a site usable for installation of a secondary battery at the location of the consumer;
calculating, using the information on used electric power and/or the information on the limitations of the area and the height accepted from the consumer, a capacity and a maximum output of a secondary battery for power storage suitable for the consumer, calculating the amount of saved power fee settled by the installation of the secondary battery, and/or calculating a cost cut effect for the consumer resulting from purchase or lease of the secondary battery based on the price of the secondary battery, the amount of saved power fee and so on; and
sending the information on the capacity and the maximum output of the secondary battery, the amount of saved power fee, and/or the cost cut effect to the consumer.

9. An information providing method according to claim 8, wherein said step of sending the information to the consumer is done through an electronic mail or the Internet.

10. An information providing method according to claim 8, wherein:
said step of calculating includes calculating a capacity of a secondary battery suitable for installation from the information on used electric power and/or the information of the limitations on the area and the height of the site for installation, and/or calculating a maximum output of the secondary battery using the capacity and a daily power consumption pattern of the used electric power.

11. An information providing method according to claim 8, wherein:
said step of calculating includes calculating a maximum output of the secondary battery suitable for installation from the information on used electric power, and/or calculating a capacity of the secondary battery using the maximum output and a daily power consumption pattern of the used electric power.

12. An information providing method according to claim 8, wherein:
said step of calculating includes calculating the amount of saved power fee using the maximum output of the secondary battery, the amount of discharge power and the amount of charge power of the secondary battery, and data on a unit power rate and a basic power rate, and/or calculating the cost cut effect using the price of the secondary battery, a use period or a lease period, and the amount of saved power fee.

13. An information providing method according to claim 8, further comprising the step of:
inquiring the consumer whether or not the consumer wishes to depute maintenance or management of the secondary battery, and when the electric power consumer so wishes, calculating the cost cut effect including a cost required for the maintenance or the management.

14. An information providing method according to claim 8, wherein:
said step of calculating includes calculating the amount of power consumed by a heater associated with a sodium/sulfur battery using the information on the number of inoperative days of the consumer and/or a temperature at the site for installation, and calculating the amount of saved power fee including the amount of power consumed by the heater.
